(19) United States
(12) Patent Application Publication
(10) Pub. No.: US 2026/0295811 A1
(43) Pub. Date: Oct. 1, 2026

(54) TRANSPORT ROBOT

(71) Applicant: NIDEC INSTRUMENTS CORPORATION, Nagano (JP)

(72) Inventor: Toshiyuki KOBAYASHI, Nagano (JP)

(73) Assignee: NIDEC INSTRUMENTS CORPORATION, Nagano (JP)

(21) Appl. No.: 19/632,413

(22) Filed: Mar. 30, 2026

(30) Foreign Application Priority Data
Mar. 31, 2025 (JP) 2025-058583

(51) Int. Cl. B25J 9/04; B25J 11/00; B25J 18/02; B25J 19/00

(52) U.S. Cl. CPC B25J 9/044; B25J 11/0095; B25J 18/02; B25J 19/0008

(57) ABSTRACT

A transport robot is provided and includes: a hand on which a workpiece is capable to be placed; an arm to which the hand is attached, the arm including one or more arm members; and an additional apparatus (electronic balance) configured to perform an operation on the workpiece. The additional apparatus is, for example, provided in an arm support member to support the arm, and moves up and down in the arm support member by a lifting mechanism that is provided in the arm support member, so as to move the additional apparatus up and down.

### CROSS-REFERENCE TO RELATED APPLICATION

This application claims the priority benefits of Japanese application no. 2025-058583, filed on Mar. 31, 2025. The entirety of the above-mentioned patent applications is hereby incorporated by reference herein and made a part of this specification.

### BACKGROUND

### Field of the Invention

At least an embodiment of the present invention relates to an industrial robot, and more particularly to a transport robot used for transporting a workpiece.

### Description of the Related Documents

A transport robot used for transporting a workpiece such as a glass substrate or a semiconductor substrate includes, for example, a base, a hand on which the workpiece is placed, an arm that is configured by linking a plurality of arm members so as to be extendable and contractible and has the hand connected to a tip thereof, an arm support member that supports the arm, and a lifting mechanism that moves the arm support member up and down relative to the base. Such a transport robot is used, for example, to transport a workpiece between a plurality of processing apparatuses that perform various processes on the workpiece. Japanese Unexamined Patent Application Publication No. 2021-027210 discloses an example of such a transport robot. The transport robot described in Japanese Unexamined Patent Application Publication No. 2021-027210 also includes a cover member that covers the workpiece being transported in order to transport a workpiece whose surface is wet with liquid.

There is a demand for inspecting a workpiece during transport of the workpiece by a transport robot, or a demand for changing the orientation of the workpiece on a hand. Conventionally, an apparatus provided separately from the transport robot has been used for inspecting a workpiece or changing the orientation of a workpiece. In that case, the workpiece was transported via the separately provided apparatus. For example, in order to measure the mass of a workpiece when transporting the workpiece from a source processing apparatus to a destination processing apparatus, a mass measuring apparatus such as an electronic balance provided separately from the transport robot is used, the workpiece is transported from the source processing apparatus to the mass measuring apparatus to measure the mass of the workpiece, and then the workpiece is transported from the mass measuring apparatus to the destination processing apparatus. In order to change the orientation of the workpiece on the hand, an apparatus called an aligner equipped with a rotary table or the like is used, and the workpiece is transported via the apparatus. Apparatuses that perform measurements related to workpieces and aligners that change the orientation of workpieces will be collectively referred to as additional apparatuses. However, transporting a workpiece via an additional apparatus provided separately from the transport robot requires time for performing processing on the workpiece in the additional apparatus, and also increases the time that the robot is actually moving for transport because the transport path of the workpiece by the robot becomes longer. Therefore, the substantial transport time from the source processing apparatus to the destination processing apparatus becomes longer, and the throughput of workpiece transport via the transport robot deteriorates.

Japanese Unexamined Patent Application Publication No. Hei 6-31667 discloses a vertical articulated robot equipped with a gripper for gripping a workpiece, in which a weight measurement sensor is provided at a wrist mechanism portion to measure the mass of the workpiece gripped by the gripper.

The robot described in Japanese Unexamined Patent Application Publication No. Hei 6-31667 can measure the mass of a workpiece, but since it is necessary to grip the workpiece, it is not suitable for transporting workpieces that are not preferred to be gripped, such as semiconductor wafers and glass substrates for liquid crystal display devices. Furthermore, since the mass measured by the weight measurement sensor includes the mass of the gripper, it is difficult to improve the measurement accuracy of the mass of the workpiece itself.

### SUMMARY

At least an embodiment of the present invention provides a transport robot capable of performing operations such as inspection on a workpiece during transport of the workpiece without increasing substantial transport time.

According to one aspect, a transport robot used for transporting a workpiece includes: a hand on which the workpiece is capable to be placed; an arm to which the hand is attached, the arm including one or more arm members; and an additional apparatus configured to perform an operation on the workpiece.

According to at least an embodiment of the present invention, it becomes possible to perform operations such as inspection on a workpiece during transport of the workpiece without increasing substantial transport time.

### BRIEF DESCRIPTION OF THE DRAWINGS

Embodiments will now be described, by way of example only, with reference to the accompanying drawings which are meant to be exemplary, not limiting, and wherein like elements are numbered alike in several figures, in which:

FIGS. 1A and 1B are a perspective view and a side view, respectively, showing a transport robot of one aspect;

FIGS. 2A and 2B are a front view and a back view, respectively, showing the transport robot;

FIGS. 3A, 3B, and 3C are a plan view, a front view, and a side view, respectively, showing a configuration of a main part of the transport robot;

FIGS. 4A and 4B are a plan view and a side view, respectively, showing the configuration of the main part of the transport robot in a state in which an arm is extended; and

FIGS. 5A and 5B are a front view and a side view, respectively, showing the configuration of the main part of the transport robot when measuring the mass of a workpiece.

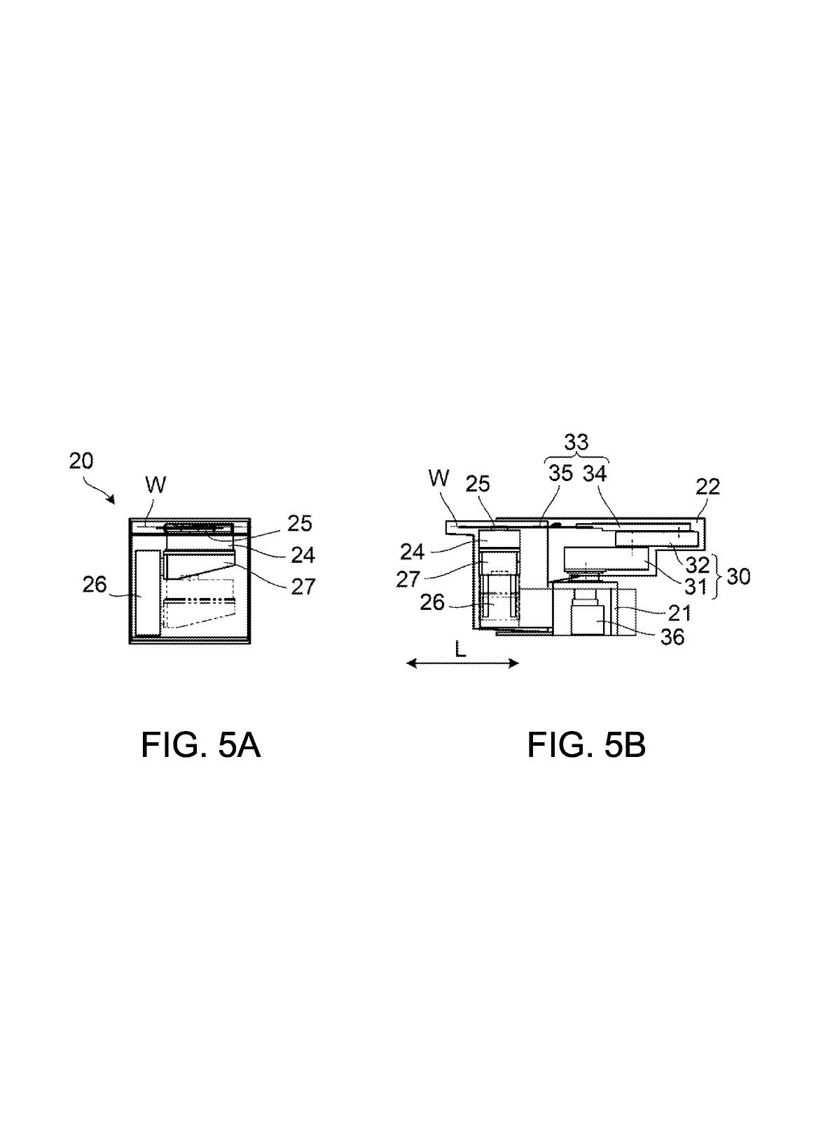

### DETAILED DESCRIPTION

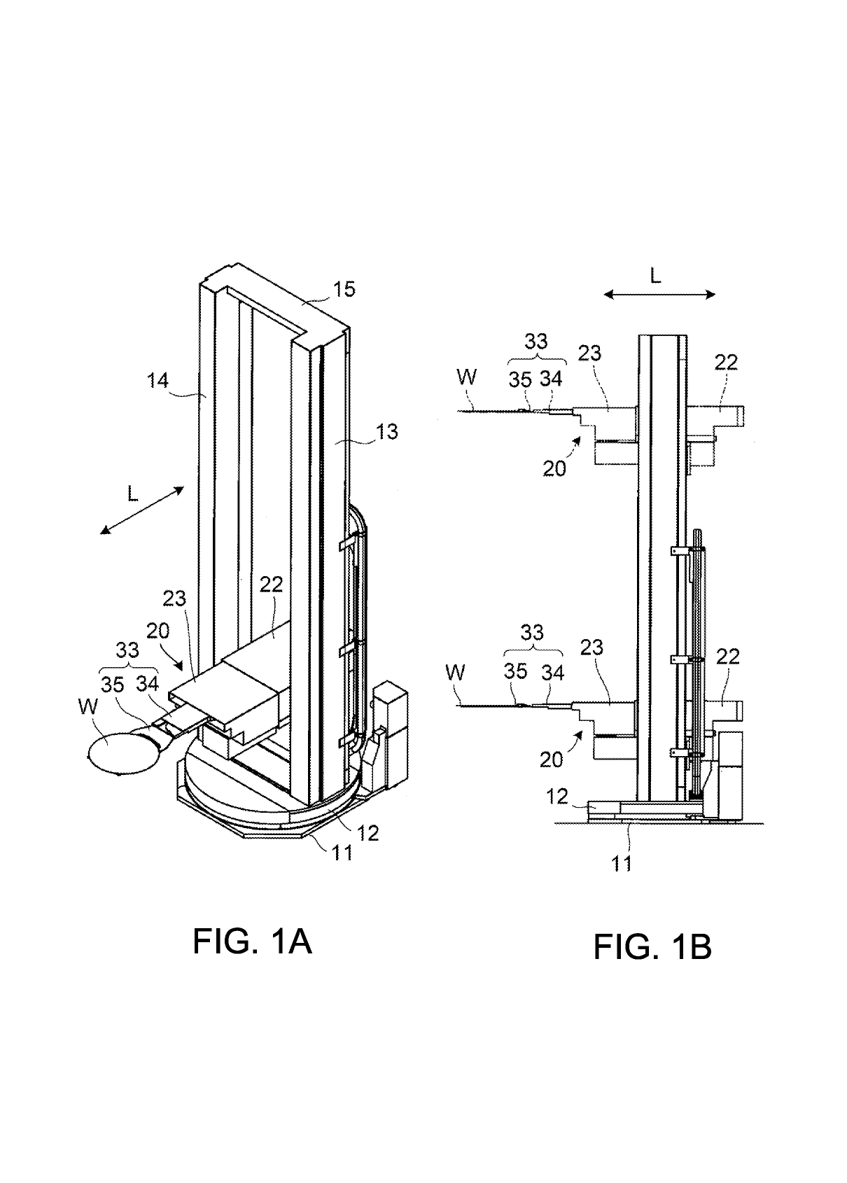

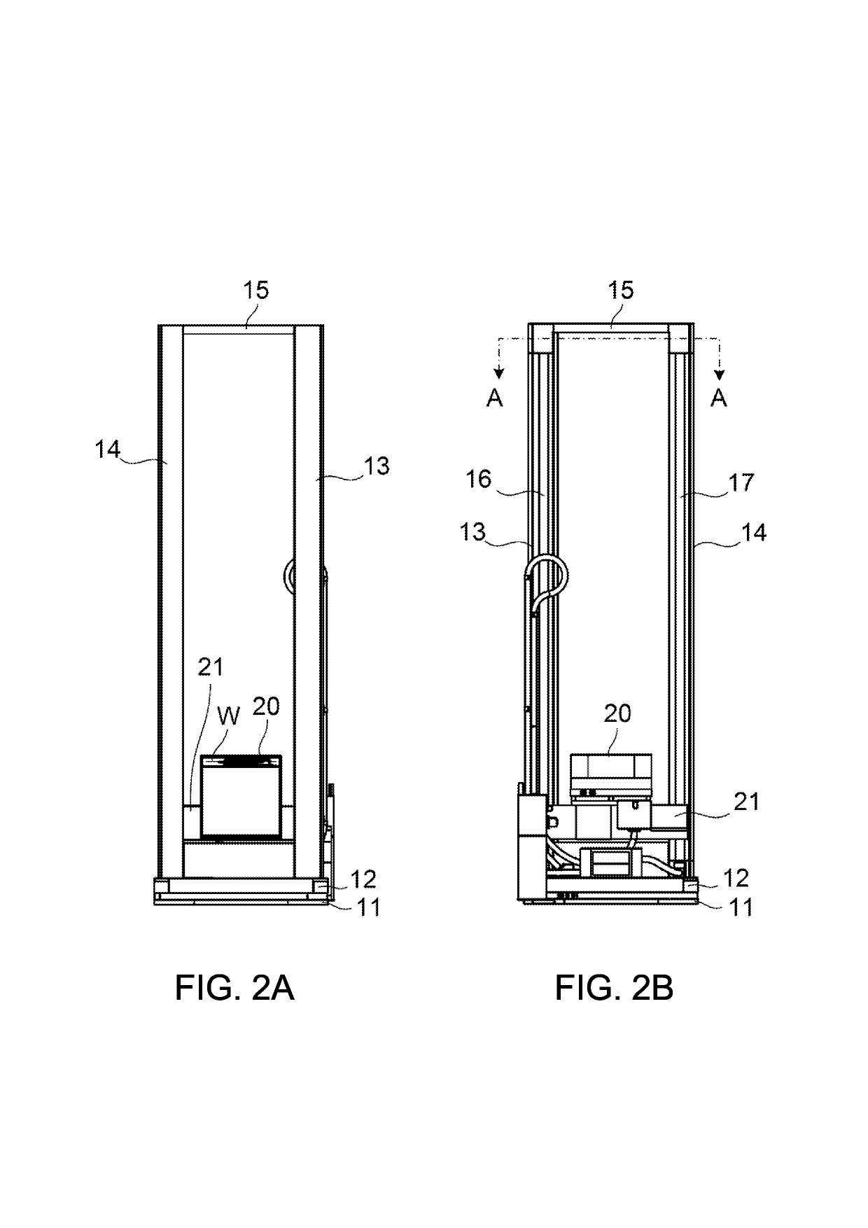

Next, embodiments of at least an embodiment of the present invention will be described with reference to the drawings. FIG. 1A is a perspective view showing a transport robot of one embodiment, and FIG. 1B is a side view of the transport robot. FIGS. 2A and 2B are a front view and a back view, respectively, of the transport robot.

The illustrated transport robot is used, for example, to transport a plate-like workpiece W such as a semiconductor wafer or a glass substrate from a processing apparatus on a carry-out side to a processing apparatus on a carry-in side while holding the workpiece W horizontally, and is similar to the transport robot described in Japanese Unexamined Patent Application Publication No. Hei 6-31667 except that an electronic balance 24, which will be described later, is provided.

The transport robot includes a base 11, and a rotary table 12 is provided on an upper surface of the base 11. The rotary table 12 is rotatable around a rotation axis extending in a vertical direction through the center of the base 11, and the rotary table 12 is driven to rotate by a motor (not shown) constituting a rotation mechanism. The rotary table 12 is provided with a pair of pillars 13 and 14 extending upward perpendicular to a horizontal plane, and upper ends of the pillars 13 and 14 are connected to each other via a top plate member 15. A portal-shaped frame is configured by the pillars 13 and 14 and the top plate member 15.

The workpiece W is placed on a hand 33 and transported. As will be described later, the hand 33 is attached to an arm 30, and the arm 30 is supported by an arm support member 20. The arm support member 20 is provided in a hollow block shape that is elongated in a direction perpendicular to an opening surface of the portal-shaped frame, that is, in a direction indicated by an arrow L in the figure. A slider 21 is attached to the arm support member 20. On the back surfaces of the pillars 13 and 14, grooves 16 and 17 extending from lower ends to upper ends of the pillars 13 and 14 are formed, respectively, and a ball screw (not shown) is provided inside each of the grooves 16 and 17. The slider 21 is provided so as to extend in a horizontal direction, and further extends into the grooves 16 and 17 of the pillars 13 and 14 and is connected to the ball screws inside the grooves 16 and 17. By driving the ball screws inside the grooves 16 and 17 to rotate, the slider 21 performs a lifting movement in an up-down direction along the surfaces of the pillars 13 and 14, and as a result, the arm support member 20 also performs a lifting movement. A lifting mechanism to move the arm support member 20 up and down is configured by the ball screws in the pillars 13 and 14 and the slider 21. Although the slider 21 is moved in the up-down direction by the ball screws to lift the arm support member 20 here, a belt may be provided in the pillars 13 and 14 instead of the ball screws, and a lifting mechanism for the arm support member 20 may be configured by the belt and the slider 21. In FIG. 1B, the arm support member 20 is drawn in two places; the arm support member 20 on the lower side of the figure shows the arm support member 20 at the lowermost position within an up-down movable range of the arm support member 20, and the arm support member 20 on the upper side of the figure shows the arm support member 20 at the uppermost position within the up-down movable range of the arm support member 20.

The hand 33 comprises a root portion 34 to be a connection portion with the arm 30, and a placement portion 35 that is at a position on a tip side of the hand 33 and is a portion on which the workpiece W is actually placed. In the illustrated example, assuming that the workpiece W is a disc-shaped semiconductor wafer, the placement portion 35 is formed in a fork shape whose tip is bifurcated.

Similar to the transport robot described in Japanese Unexamined Patent Application Publication No. Hei 6-31667, the transport robot of the present embodiment also comprises a pair of protective covers 22 and 23 in order to prevent liquid or the like from spilling and scattering around the transport robot during transport of the workpiece W when the liquid or the like is present on the surface of the workpiece W. One protective cover 22 is fixed to the arm support member 20, and the other protective cover 23 is configured to move according to the movement of the hand 33. Since the configuration of the protective covers 22 and 23 and the mechanism for driving the protective cover 23 are the same as those described in Japanese Unexamined Patent Application Publication No. Hei 6-31667, detailed descriptions thereof are omitted.

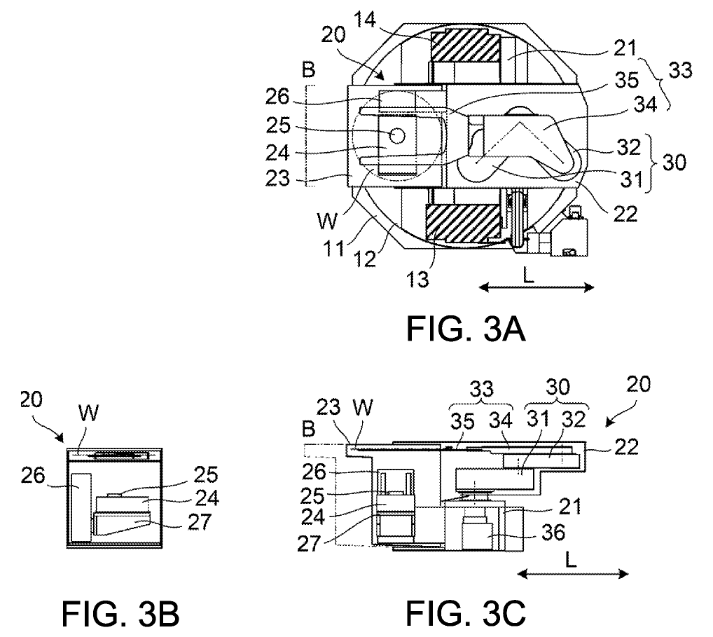

FIGS. 3A, 3B, and 3C all show the arm support member 20, the arm 30, and the hand 33 as main parts of the transport robot. FIG. 3A is a plan view showing the arm support member 20, the arm 30, and the hand 33 as a cross-sectional view along the line A-A in FIG. 2B, FIG. 3B is a front view of the arm support member 20 shown so that the internal configuration of the arm support member 20 can be understood, and FIG. 3C is a side view of the arm support member 20 shown so that the internal configuration of the arm support member 20 can be understood. FIG. 3A is drawn as a perspective view of the upper surfaces of the protective covers 22 and 23. In FIG. 3B, the slider 21 is not drawn for easy understanding of the description.

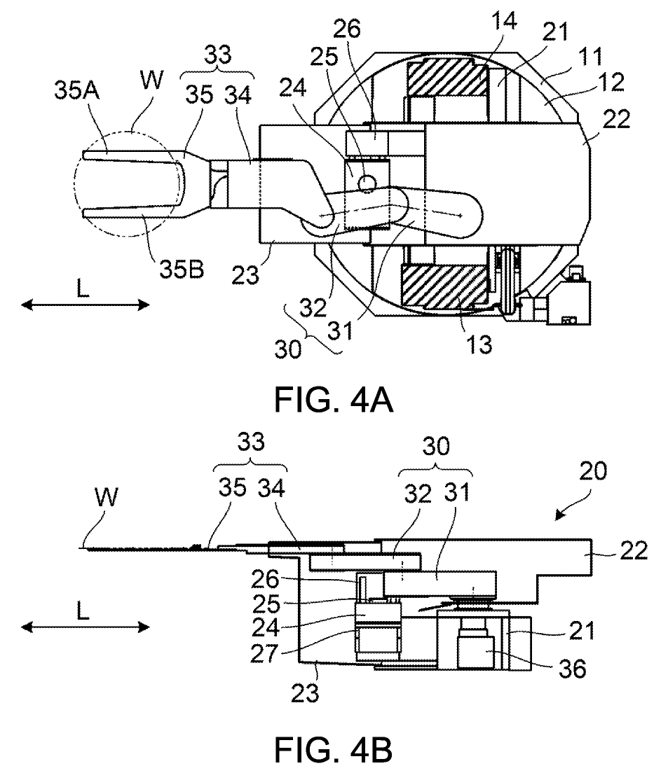

The arm 30 is formed by linking a first arm member 31 and a second arm member 32. One end of the first arm member 31 is attached to the arm support member 20 so that the first arm member 31 is rotatable in a horizontal plane. One end of the second arm member 32 is attached to the other end of the first arm member 31 so that the second arm member 32 is rotatable in a horizontal plane. The hand 33 has its root portion 34 attached to the other end of the second arm member 32 so that the hand 33 is rotatable in a horizontal plane. A motor 36 to drive the first arm member 31 to rotate relative to the arm support member 20 is also attached to the arm support member 20. In practice, a link mechanism is provided inside the first arm member 31 and the second arm member 32 so that the hand 33 performs a linear movement in the L direction without changing its orientation by driving the motor 36 to rotate. In this case, the arm 30 extends and contracts along the L direction as the motor 36 rotates. In a state in which the arm 30 is extended (that is, a first state), the hand 33 is at a position advanced in the horizontal direction from a position on the arm support member 20. When receiving or delivering the workpiece W from or to a processing apparatus, the arm 30 is in the extended state in order to cause the hand 33 to enter the processing apparatus. On the other hand, in a state in which the arm 30 is contracted (that is, a second state), the hand 33 is located completely above the arm support member 20. The arm 30 extends and contracts by transitioning between the first state and the second state. In the state in which the arm 30 is contracted, the rotary table 12 can be rotated around the base 11 and the arm support member 20 can be moved up and down without interfering with the processing apparatus or other objects. In addition to driving the arm 30, the motor 36 also moves the protective cover 23 according to the extension and contraction of the arm 30. FIGS. 3A, 3B, and 3C show a state in which the arm 30 is contracted. In FIGS. 3A and 3C, the outline of the protective cover 23 when the arm 30 is extended is indicated by reference symbol B. FIG. 4A is a plan view similar to FIGS. 3A, and 4B is a side view similar to FIG. 3C, but FIGS. 4A and 4B show the state in which the arm 30 is extended.

When transporting the workpiece W using the transport robot of the present embodiment, first, in the state in which the arm 30 is contracted, the rotary table 12 is rotated and the arm support member 20 is moved up and down so that the arm support member 20 faces the carry-out/in port of the source processing apparatus, then the arm 30 is extended to cause the hand 33 to enter the carry-out/in port of the source, and the workpiece W is placed on the placement portion 35 of the hand 33. This operation is called a Get operation. Next, after setting the arm 30 to the contracted state while holding the workpiece W, the rotary table 12 is rotated and the arm support member 20 is moved up and down so that the arm support member 20 faces the carry-out/in port of the destination processing apparatus. Thereafter, the arm 30 is extended to cause the hand 33 to enter the carry-out/in port of the destination, and the workpiece W on the placement portion 35 of the hand 33 is unloaded to the processing apparatus side. This operation is called a Put operation. In the process of transporting the workpiece W from the source processing apparatus to the destination processing apparatus, the state in which the arm 30 is contracted is always passed through. In the workpiece transport apparatus of the present embodiment, an additional apparatus that performs some operation on the workpiece W is attached to the transport robot, and the operation is performed on the workpiece W by the additional apparatus in the state in which the arm 30 is contracted for transport. Examples of the operation on the workpiece W include measuring the mass of the workpiece W, or changing the orientation of the workpiece W. In the following description, a case where measurement of the mass of the workpiece W is performed as an operation on the workpiece W will be described.

The arm support member 20 is provided with an electronic balance 24 that measures mass, and a lifting mechanism 26 that moves the electronic balance 24 up and down in the arm support member 20. The lifting mechanism 26 comprise a main body portion fixed to the arm support member 20, and a lifting platform 27 that moves up and down relative to the main body portion, and the electronic balance 24 is installed on the lifting platform 27. A weighing unit (not shown) configured by a load cell or an electromagnetic coil or the like is provided inside the electronic balance 24, and a detection unit 25 mechanically connected to the weighing unit protrudes from the upper surface of the electronic balance 24. The electronic balance 24 is configured to measure the mass of an object placed on the detection unit 25. The electronic balance 24 is arranged in the arm support member 20 such that the detection unit 25 is located directly below the center of the workpiece W placed on the hand 33 in the state in which the arm 30 is contracted. Normally, the electronic balance 24 is at a position lowered in the arm support member 20 by the lifting mechanism 26, as shown in FIGS. 3B and 3C. In this state, the electronic balance 24 and its detection unit 25 do not interfere with the extension and contraction of the arm 30 or the movement of the hand 33. When measuring the mass of the workpiece W, it is raised in the arm support member 20 by the lifting mechanism 26 so that the detection unit 25 contacts the lower surface of the workpiece W. When the detection unit 25 contacts and the workpiece W is slightly lifted from the hand 33, the lifting mechanism 26 is kept stationary in that state so that the total mass of the workpiece W acts on the detection unit 25. As a result, the weighing unit inside the electronic balance 24 can measure the mass of the workpiece W via the detection unit 25. After the measurement of the mass is completed, the electronic balance 24 is lowered again by the lifting mechanism 26. Since the placement portion 35 of the hand 33 is bifurcated and provided with two forks 35A and 35B in the illustrated example, no fork is present at a position directly above the detection unit 25. Therefore, the detection unit 25 can be brought into contact with the lower surface of the workpiece W without interfering with the hand 33.

Since vibration causes noise and errors in mass measurement, it is preferable that the transport robot is stationary during measurement of the mass of the workpiece W by the electronic balance 24. That is, it is preferable that the rotation by the rotary table 12 and the lifting movement of the arm support member 20 are stopped. However, if the influence of vibration generated in the transport robot is negligible, the mass of the workpiece W can be measured even during execution of rotation by the rotary table 12 and lifting movement of the arm support member 20 for transport of the workpiece W. In a case where an additional apparatus separate from the robot is provided to measure the mass of the workpiece W there, time for transporting the workpiece W from the source processing apparatus to the additional apparatus, time for measurement in the additional apparatus, and time for transporting the workpiece W from the additional apparatus to the destination processing apparatus are required. In contrast, in the case of the present embodiment, although time required for measurement by the electronic balance 24 corresponding to the additional apparatus is necessary, it is only necessary to directly transport the workpiece W from the source processing apparatus to the destination processing apparatus, so that the total required time can be reduced compared to the case where an additional apparatus is provided separately from the robot. If the robot can actually move during mass measurement by the electronic balance 24, the total required time can be further shortened according to the present embodiment. Furthermore, since the protective covers 22 and 23 are provided on the arm support member 20, the mass of the workpiece W can be measured without being affected by airflow or the like.

In the above, the case where the additional apparatus provided on the arm support member 20 to perform an operation on the workpiece W during transport is the electronic balance 24 has been described, but the additional apparatus may be an apparatus other than the electronic balance 24. For example, an aligner that rotates the workpiece W horizontally placed on the hand 33 to change the orientation of the workpiece W in a horizontal plane can be provided as an additional apparatus. When an aligner is provided as an additional apparatus, the aligner may be attached to the lifting mechanism 26 such that the rotation axis of the aligner protrudes from the main body of the aligner, similarly to the detection unit 25 in the electronic balance 24. When changing the orientation of the workpiece W, the aligner is raised so that the rotation axis contacts the lower surface of the workpiece W and the workpiece W is slightly lifted from the hand 33, and the rotation axis may be rotated in that state to bring the workpiece W into a desired orientation. Thereafter, the aligner is lowered again.

According to the transport robot of the present embodiment described above, it is possible to measure the mass of the workpiece W or change the orientation of the workpiece W while holding the workpiece W horizontally during transport of the workpiece W without substantially increasing the time required to transport the workpiece W from the source to the destination.

An example of a configuration for carrying out at least an embodiment of the present invention has been described above, but the above technology can take the following configurations.

[1] A transport robot used for transporting a workpiece, including: a hand on which the workpiece is capable to be placed; an arm to which the hand is attached, the arm including one or more arm members; and an additional apparatus configured to perform an operation on the workpiece.

According to the configuration of [1], since the additional apparatus that performs an operation on the workpiece is provided in the transport robot itself, the time to move the workpiece to the additional apparatus can be shortened compared to a case where an additional apparatus is provided independently of the robot.

[2] The transport robot according to [1], further including: an arm support member configured to support the arm; and a first lifting mechanism configured to move the additional apparatus up and down, the first lifting mechanism being provided in the arm support member.

[3] The transport robot according to [2], wherein the arm is configured by linking the plurality of arm members so that the arm members are connected to each other and each of the arm members is rotatable in a horizontal plane, the hand is connected to the arm member at a tip of the arm so as to be rotatable in a horizontal plane, and the additional apparatus rises when the operation is performed on the workpiece and the additional apparatus lowers when the operation is completed.

[4] The transport robot according to [3], wherein the arm is extendable and contractible, and the hand is at a position on the arm support member such that in a first state in which the arm is extended, the hand is at a position advanced in a horizontal direction from a position on the arm support member, and in a second state in which the arm is contracted, the workpiece placed on the hand comes to a position directly above the additional apparatus.

According to the configuration of [2], by providing the additional apparatus in the arm support member that supports the arm and enabling the additional apparatus to be lifted up and down, the configuration of the transport robot can be simplified, and the additional apparatus can be prevented from interfering with the movement of the arm. In particular, according to the configuration of [3], it is possible to prevent the additional apparatus from interfering with the movement of the arm in a case where a horizontal articulated arm is provided, and according to the configuration of [4], the operation can be performed on the workpiece by the additional apparatus when the arm is in the second state and the hand is on the arm support member. If the arm necessarily enters the second state during transport of the workpiece, the operation can be performed on the workpiece by the additional apparatus at that time, so that the operation can be performed on the workpiece without increasing substantial transport time.

[5] The transport robot according to [4], wherein the additional apparatus is an electronic balance in which a detection unit to detect mass is provided protruding, and when the additional apparatus is raised by the first lifting mechanism, the detection unit contacts a lower surface of the workpiece to measure the mass of the workpiece.

[6] The transport robot according to [4], wherein the additional apparatus is an aligner whose rotation axis is exposed, and when the additional apparatus is raised by the first lifting mechanism, an end of the rotation axis contacts a lower surface of the workpiece, and the orientation of the workpiece is changed by rotating the rotation axis in a state in which the end of the rotation axis is in contact with the lower surface of the workpiece.

According to the configuration of [5], it becomes possible to measure the mass of the workpiece during transport of the workpiece or the like, and according to the configuration of [6], the orientation of the workpiece can be changed during transport of the workpiece or the like.

[7] The transport robot according to any one of [4] to [6], further including: a base; a rotary table rotatable around an axis perpendicular to the base; a rotation mechanism to rotate the rotary table relative to the base; a frame to be attached to the rotary table and hold the arm support member so as to be movable up and down; and a second lifting mechanism to move the arm support member up and down relative to the frame, wherein the rotation mechanism and the second lifting mechanism operate when the arm is in the second state.

According to the configuration of [7], when transporting a workpiece or the like between a plurality of processing apparatuses provided so as to surround a space where the transport robot is arranged, an operation can be performed on the workpiece by the additional apparatus during transport of the workpiece while preventing the transport robot from interfering with surrounding objects or the like and also preventing the transport time from becoming substantially longer.

What is claimed is:

1. A transport robot used for transporting a workpiece, comprising:
a hand on which the workpiece is capable to be placed;
an arm to which the hand is attached, the arm comprising one or more arm members; and
an additional apparatus configured to perform an operation on the workpiece.

2. The transport robot according to claim 1, further comprising:
an arm support member configured to support the arm; and
a first lifting mechanism configured to move the additional apparatus up and down, the first lifting mechanism being provided in the arm support member.

3. The transport robot according to claim 2, wherein
the arm is configured by linking a plurality of the arm members so that the arm members are connected to each other and each of the arm members is rotatable in a horizontal plane,
the hand is connected to the arm member at a tip of the arm so as to be rotatable in a horizontal plane, and
the additional apparatus rises when the operation is performed on the workpiece, and the additional apparatus lowers when the operation is completed.

4. The transport robot according to claim 3, wherein
the arm is extendable and contractible,
the hand is at a position on the arm support member such that in a first state in which the arm is extended,
the hand is at a position advanced in a horizontal direction from a position on the arm support member, and in a second state in which the arm is contracted, the workpiece placed on the hand comes to a position directly above the additional apparatus.

5. The transport robot according to claim 4, wherein
the additional apparatus is an electronic balance in which a detection unit to detect mass is provided protruding, and
when the additional apparatus is raised by the first lifting mechanism, the detection unit contacts a lower surface of the workpiece to measure mass of the workpiece.

6. The transport robot according to claim 4, wherein
the additional apparatus is an aligner whose rotation axis is exposed, and
when the additional apparatus is raised by the first lifting mechanism, an end of the rotation axis contacts a lower surface of the workpiece, and
an orientation of the workpiece is changed by rotating the rotation axis in a state in which the end of the rotation axis is in contact with the lower surface of the workpiece.

7. The transport robot according to claim 4, further comprising:
a base;
a rotary table rotatable around an axis perpendicular to the base;
a rotation mechanism to rotate the rotary table relative to the base;
a frame to be attached to the rotary table and hold the arm support member so as to be movable up and down; and
a second lifting mechanism to move the arm support member up and down relative to the frame,
wherein the rotation mechanism and the second lifting mechanism operate when the arm is in the second state.

8. The transport robot according to claim 5, further comprising:
a base;
a rotary table rotatable around an axis perpendicular to the base;
a rotation mechanism to rotate the rotary table relative to the base;
a frame to be attached to the rotary table and hold the arm support member so as to be movable up and down; and
a second lifting mechanism to move the arm support member up and down relative to the frame,
wherein the rotation mechanism and the second lifting mechanism operate when the arm is in the second state.

9. The transport robot according to claim 6, further comprising:
a base;
a rotary table rotatable around an axis perpendicular to the base;
a rotation mechanism to rotate the rotary table relative to the base;
a frame to be attached to the rotary table and hold the arm support member so as to be movable up and down; and
a second lifting mechanism to move the arm support member up and down relative to the frame,
wherein the rotation mechanism and the second lifting mechanism operate when the arm is in the second state.
